(19) United States
(12) Patent Application Publication
(10) Pub. No.: US 2026/0219307 A1
(43) Pub. Date: Jul. 30, 2026

(54) Near Field Apparatus and Methods For Emulating A Far Field 3D Antenna Pattern

(71) Applicant: Matsing, Inc., Irvine, CA (US)

(72) Inventors: Alexander Zubov, Singapore (SG); Serguei Matitsine, Dallas, TX (US)

(21) Appl. No.: 19/041,674

(22) Filed: Jan. 30, 2025

(51) Int. Cl. G01R 29/10; G01R 29/08

(52) U.S. Cl. CPC G01R 29/10; G01R 29/0878; G01R 29/0892

(57) ABSTRACT

A far-field 3D radiation pattern for an antenna under test (AUT) is simulated by a near-field system using at data from one of the scanners to augment/extrapolate data from at least one other scanner. A smoothing function can be used to reduce anomalous oscillations in the augmented/extrapolated data.

### FIELD OF THE INVENTION

The field of the invention is RF antennas.

### BACKGROUND

The background description includes information that may be useful in understanding the present invention. It is not an admission that any of the information provided herein is prior art or relevant to the presently claimed invention, or that any publication specifically or implicitly referenced is prior art.

A wide variety of antenna measurement systems have been developed over the past century. Far-field antenna measurements typically measure the AUT (antenna under test) with a plane wave front (or close to a plane wavefront) to obtain direct real time antenna measurements (such as antenna pattern measurements). However, this approach requires a large distance between the AUT and the emitter (typically Distance=2d²/λ) and therefore can be costly or not possible for larger size antennas. With the advent of accurate measurement equipment and low-cost, powerful computing, the most widely used are near-field systems, where the field radiated by the antenna is measured on a nearby surface, partially or completely surrounding the antenna.

There are a limited number of surfaces which make it possible to calculate the far-field pattern, knowing only the tangential components of the electrical field on that surface. The collected data is then transformed using mathematical algorithms to simulate far-field data. There are different configurations of near-field systems, the most common systems are planar (where radiation data from the AUT is collected in XY plane, although it can include collecting in just the X or Y plane), cylindrical (where data is collected in a cylindrical surface/or cylindrical scanning area around the AUT, and spherical (where data is collected in a spherical surface/scanning area around the AUT).

Near-field systems use scanners to collect this data. Most typically a scanner comprises a single probe moveable on a track, and a positioner to rotate the AUT. Other systems use multiple probes, as well as systems that use single probes on a non-linear track. Spherical near-field systems are considered the most comprehensive, as measurements are made on a spherical surface, which allow one to reconstruct the full 3D pattern. For all types of near-field systems it is desired to measure all the significant AUT radiated energy, which can require large scanning areas/planes in order to collect the necessary data.

Another approach to obtain a full 3D pattern is to use hybrid protocols, where the field is measured on 2 planes and one cylindrical surface, or on 6 mutually perpendicular plane surfaces surrounding the antenna. Antenna patterns are reconstructed in a limited range of angles for each canonical surface used (3 for the first case and 6 for the second), and after that the calculated patterns are stitched to obtain a full 3D pattern.

A significant problem with hybrid approaches is that even without considering diffraction effects, an appropriate size of the scanning area (the height of the cylinder or the size of the side of the plane) is generally thought to be larger than the diameter of the AUT (in the case of a Luneburg lens antenna the scanning area would be at least 2.4 times larger than the diameter of the Luneburg lens antenna). A Luneburg lens spherical antenna will be used as an example for all drawings described herein. For other types of antennas, including elongated base station antennas, the required scanning distance is also thought to be much higher than the perimeter of the largest cross-section. In other words, scanning area required is significantly larger than the size of the AUT.

One type of near-field system involves measuring on just a cylindrical surface surrounding the antenna. This technique does not measure on a completely closed surface around the antenna, so it is not possible to calculate a complete 3D pattern, a conical zone above and below the antenna are missing.

The bottom line is that although near-field measurement systems can provide a good solution for measuring 2D and 3D patterns, the prior art has required large scanners/large scanning areas (multiple times the size of the antenna) in order to adequately collect the necessary data. What is still needed is a system of using near-field measurements to calculate full 3D antenna patterns, with significantly reduced scanning area.

The following description includes information that may be useful in understanding the present invention. It is not an admission that any of the information provided herein is prior art.

As used in the description herein and throughout the claims that follow, the meaning of “a,” “an,” and “the” includes plural reference unless the context clearly dictates otherwise. Also, as used in the description herein, the meaning of “in” includes “in” and “on” unless the context clearly dictates otherwise.

The recitation of ranges of values herein is merely intended to serve as a shorthand method of referring individually to each separate value falling within the range. Unless otherwise indicated herein, each individual value is incorporated into the specification as if it were individually recited herein. All methods described herein can be performed in any suitable order unless otherwise indicated herein or otherwise clearly contradicted by context. The use of any and all examples, or exemplary language (e.g. “such as”) provided with respect to certain embodiments herein is intended merely to better illuminate the invention and does not pose a limitation on the scope of the invention otherwise claimed. No language in the specification should be construed as indicating any non-claimed element essential to the practice of the invention.

### SUMMARY OF THE INVENTION

The inventive subject matter provides apparatus, systems and methods in which near-field measurements are used to calculate full 3D antenna patterns, with significantly reduced scanning area. In particular, data collected from one near-field scanning area/plane is used to approximate data for a different near-field scanning area/plane, thereby removing the need to use large scanning areas to collect all necessary data. In one example, the radiation pattern from an antenna under test (AUT) is scanned using orthogonal scanners, and simulated cylindrical and planar scanning surfaces.

In particular, data from one or more simulated surfaces (primary surface) can be used to augment/extrapolate data in one or more of the other simulated scanning surfaces (secondary surface). For example, data from a simulated planar surface can be used to augment/extrapolate data in a simulated cylindrical surface, or visa versa.

To minimize anomalous oscillations in the collected data, known as the Gibbs effect, a smoothing function can be applied, decreasing from an inner boundary of a simulated extension surface to an outer boundary of the simulated extension surface. Independently, a compensation function can be applied to the data collected from a primary surface, and a reverse compensation function can be applied to measured data from a secondary surface.

Where a cylinder scan is used to create a simulated cylindrical surface, one or both of an AUT and a scanner can be rotated. 3D data can be collected by flipping the AUT around an axis perpendicular to the longitudinal axis of the simulated cylinder, or the axis about which the rotating probe rotates.

Physical scanners are preferably located at a distance of not less than 2 wavelengths from the AUT.

Various objects, features, aspects and advantages of the inventive subject matter will become more apparent from the following detailed description of preferred embodiments, along with the accompanying drawing Figures in which like numerals represent like components.

### BRIEF DESCRIPTION OF THE DRAWING

FIG. 1 is a diagram of a first embodiment of a near-field antenna measurement system. The left drawing shows a simulated AUT surrounded by several simulated scanning surfaces/scanning areas, and the right drawing shows the corresponding physical AUT and physical scanners. This embodiment has extended simulated planar surfaces, and uses a single rotation axis.

FIG. 2 is a diagram of a first embodiment of a near-field antenna measurement system. The left drawing shows a simulated AUT surrounded by several simulated scanning surfaces/scanning areas, and the right drawing shows the corresponding physical AUT and physical scanners. This embodiment uses a single rotation axis.

FIG. 3 is a diagram of a third alternative embodiment of an antenna measurement system that is similar to FIG. 1 but uses two axis of rotation.

FIG. 4 is a diagram of a fourth alternative embodiment of an antenna measurement system that is similar to FIG. 2, but uses two axis of rotation.

FIG. 5 is a diagram of the antenna measurement system of FIG. 1, where the AUT is an elongated base station.

FIG. 6 is a diagram of an example of the method of testing, with an antenna under test being scanned by an antenna measurement system mounted on a scanning carriage, using inventive protocols discussed herein.

FIG. 7 is a diagram of an example of the method of testing, with an antenna under test being scanned by an alternative antenna measurement system mounted on a scanning carriage, using inventive protocols discussed herein.

### DETAILED DESCRIPTION

### First Embodiment: Near Field System with Single Axis of Rotation and Simulated Planer Surfaces Extending Beyond Simulated Cylindrical Surface

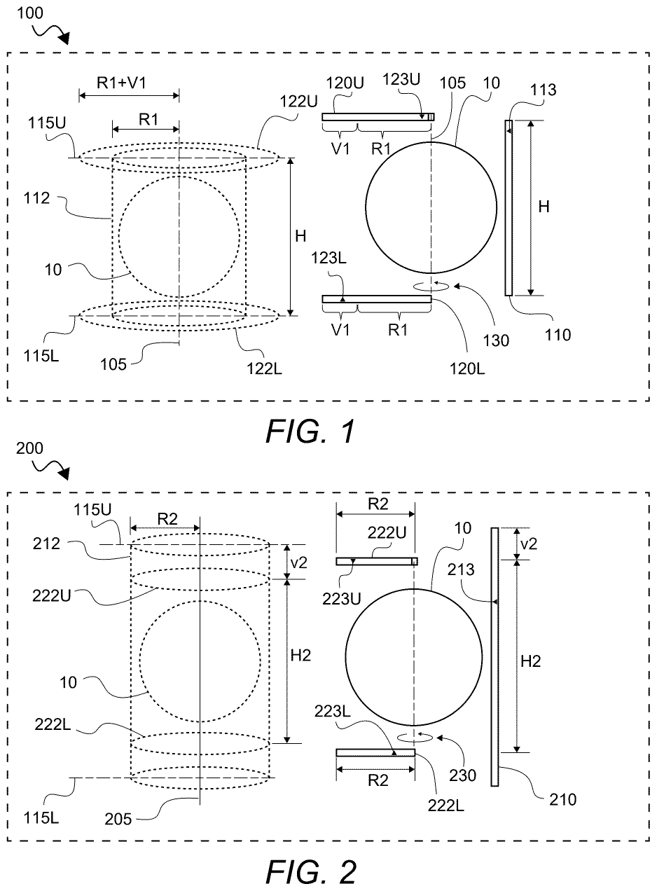

In FIG. 1, antenna measurement system 100 generally comprises three scanners 110, 120U, 120L positioned about an Antenna Under Test (AUT) 10. The scanners 110, 120U, 120L should be understood to include physical probes 113, 123U, 123L, respectively, movable along their respective tracks.

Data collected by scanner 110 as AUT 10 rotates around axis 130 produces simulated cylindrical scanning surface (cylinder) 112 having radius R1 and height H1. Data collected by scanners 120U, 120L produce simulated planar scanning surfaces 122U, 122L. In FIG. 1, the simulated planar scanning surfaces 122U, 122L extend laterally beyond the lateral edge of the simulated cylindrical scanning surface 112. Instead of, or in addition to rotation of AUT 10 about axis 130, scanner 110 could revolve about axis 130.

The simulated scanning surfaces 123U, 123L extend laterally beyond the cylinder 112 by a distance V1. Realistically, scanning on planes defined by scanning surfaces 123U, 123L is limited to a circle of radius R1+V1, where V1 is equal to at least 3-5 wavelengths, with the wavelength varying depending on what frequency/wavelength is used for the testing. In FIG. 1 and other Figures, scanning is preferably carried out in steps of less than a half wavelength, however different steps can be used with varying degrees of accuracy (smaller scanning steps producing better data). In each of the embodiments herein, AUTs are contemplated to be scanned using wavelengths between 1 mm and 1000 mm.

Scanning along the scanning lines 115U, 115L of the upper and lower simulated scanning surfaces 123U, 123L, respectively, preferably starts from the AUT rotation axis 130, and moves outward at an arbitrary azimuth angle. A positioner (not shown) is used to rotate AUT 10 and/or scanner 110, and the scanning step is repeated for each incremental movement of the positioner.

A suitable algorithm for calculating the full antenna pattern is as follows:
1. The measured field in the ring from R1 to R1+V1 is multiplied by a smoothing function equal to 1 at the inner boundary and decreasing to 0 towards the outer boundary. This operation significantly reduces the effect of data discontinuity across the field at the edge of the measurement area.
2. The field is decomposed into a spectrum of plane waves, after which the influence of the probe's pattern on the spectrum of the received field is compensated.
3. The spectrum of plane waves is distorted as if it were received by a probe scanning along the vertical axis.
4. Using the compensated spectrum of plane waves, the field on the extension of the cylindrical surface is calculated. This is possible because all sources are located inside the cylinder and there are no sources outside the cylinder.
5. The field on the surface of the extended simulated cylinder is transformed into 3D far-field patterns. Because of an increase in the height of the simulated cylinder, the field now can reach 2-10 times, then the angular region of reconstruction of the antenna pattern increases significantly. Near field systems use transformations between the near field and far field. In practical systems band widths are limited, and this results in errors in the transformations. One known error that is usually expressed as a type of “ringing” is known as Gibbs phenomenon. To reduce the Gibbs phenomenon, 5-10% of the area near the edges can advantageously be multiplied by a smoothing function before near field to far field transformation.
6. The remaining part of the full 3D antenna pattern is obtained by transformation of the fields in the upper and lower scanning planes into an antenna pattern with standard probe pattern compensation. The multiplication by the smoothing function from step 1 is retained before transformation.

By applying the above described processes including the smoothing function, it is possible to extrapolate/approximate data on the vertical plane by collecting additional data on the horizontal plane. This allows for a much smaller scanning area to be used to still be able to receive a 3D measurement pattern.

### Second Embodiment: Near Field System with Single Axis of Rotation and Simulated Planer Surfaces Extending to Edge of Simulated Cylindrical Surface

In FIG. 2, antenna measurement system 200 generally comprises three scanners 210, 220U, 220L positioned about the Antenna Under Test (AUT) 10. The scanners 210, 220U, 220L should be understood to include physical probes 213, 223U, 223L, respectively, movable along their respective tracks.

Data collected by scanner 210 as AUT 10 rotates around axis 230 produces simulated cylindrical scanning surface 212 having radius R2 and height H2 Data collected by scanners 220U, 220L produce simulated planar scanning surfaces 222U, 222L. In FIG. 2, the simulated planar scanning surfaces 222U, 222L extend laterally only up to the lateral edge of the simulated cylindrical scanning surface 212. Here also, scanner 210 could revolve about axis 230 instead of, or in addition to rotation of AUT 10 about axis 230,

The scanning surfaces 213, 223U, 223L are collectively used to scan two orthogonal tangential components of electric field emitted by the AUT 10. V2 is equal to at least 3-5 wavelengths. Scanning is performed using relevant protocols discussed above.

A suitable algorithm for calculating the full 3D antenna pattern is similar to that used with antenna measurement system 100 the first embodiment, with the exception that the field measured on a cylindrical surface is decomposed into the spectrum of cylindrical waves, and after compensation of the probe patterns, the fields are found on the continuation of planar surfaces outside of radius R2, inside of which we already know measured data.

### Third Embodiment: Near Field System with Two Axes of Rotation and Simulated Planer Surfaces Extending Beyond Simulated Cylindrical Surface

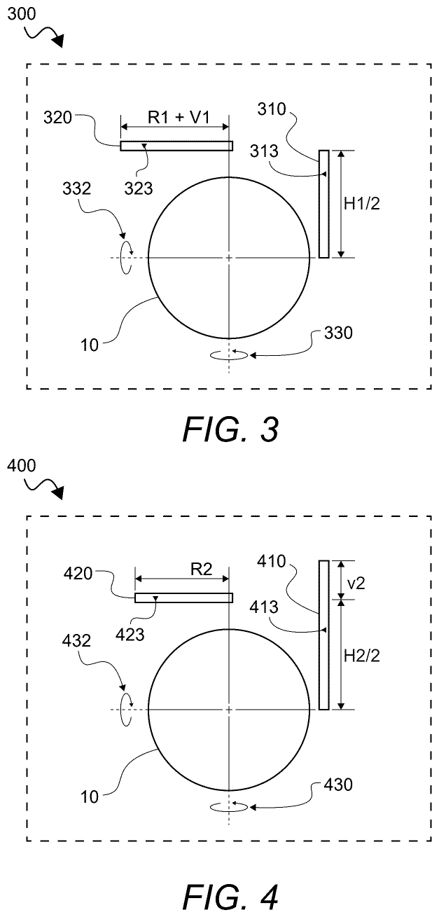

In FIG. 3, antenna measurement system 300 is a variant of the system 100, where the simulated cylindrical scanning surface 112 is not shown, scanner 320 corresponds to scanner 120U, probe 323 corresponds to probe 123U, scanner 310 corresponds to scanner 110, and probe 313 corresponds to probe 113. Here, scanner 310 is only half the height of scanner 110, and AUT 10 is rotatable about two axes 330 and 332. There is no corresponding component to scanner 120L. The measurement process remains the same as for embodiments in FIGS. 1 and 2, but is repeated two times—first as AUT 10 is rotated about one of axes 330, 332, and then again as the AUT 10 is rotated 180 degrees about the other axis. Scanning is performed using relevant protocols discussed above.

### Fourth Embodiment: Near Field System with Two Axes of Rotation and Simulated Planer Surfaces Extending to Edge of Simulated Cylindrical Surface

In FIG. 4, antenna measurement system 400 is a variant of the system 200, where the simulated cylindrical scanning surface 212 is not shown, scanner 420 corresponds to scanner 320U, probe 423 corresponds to probe 423U, scanner 410 corresponds to scanner 210, and probe 413 corresponds to probe 213. Here, probe 410 is half the height of probe 110, plus V 2, and AUT 10 is rotatable about two axes 430 and 432. There is no corresponding component to probe 220L. The measurement process remains the same as for embodiments in FIGS. 1 and 2, but is repeated two times—first as AUT 10 is rotated about one of axes 430, 432, and then again as the AUT 10 is rotated 180 degrees about the other axis. Scanning is performed using relevant protocols discussed above.

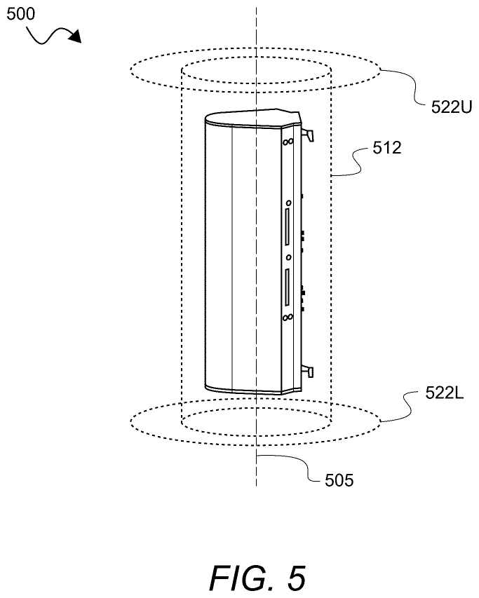

In FIG. 5, antenna measurement system 500 is the same as antenna measurement system 100, but shown with an elongated base station 510 in place of AUT 10. Here, simulated cylindrical scanning surface 512 corresponds to simulated cylindrical scanning surface 112, simulated planar scanning surface 522U corresponds to simulated cylindrical scanning surface 122U, simulated planar scanning surface 522L corresponds to simulated cylindrical scanning surface 122L. Elongated base station 510 is rotatable about axis 505. Scanning is performed using relevant protocols discussed above.

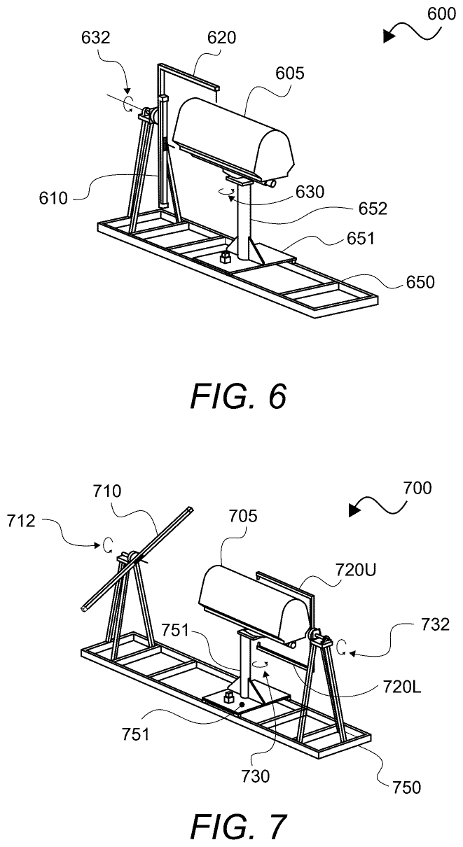

In FIG. 6, an Antenna Under Test 605 is being scanned using relevant protocols discussed above, by an antenna measurement system 600 mounted on semi-transparent carriage 650. Antenna measurement system 600 generally includes mutually orthogonal probes 610, 620 rotatable about axis 632. AUT 605 is horizontally rotatable about axis 630, and positioned vertically by post 630 and horizontally by slider 651.

In FIG. 7, an Antenna Under Test 705 is being scanned using relevant protocols discussed above, by an alternative antenna measurement system mounted 700 on semi-transparent carriage 750. Antenna measurement system 700 generally includes mutually parallel probes 720U, 720L and probe 710. Scanners 720U, 720L are revolvable about axis 732, and probe 710 is rotatable about axis 712. AUT 705 is rotatable about axis 730, and positioned vertically by post 730 and horizontally by slider 751.

It should be apparent to those skilled in the art that many more modifications besides those already described are possible without departing from the inventive concepts herein. The inventive subject matter, therefore, is not to be restricted except in the spirit of the appended claims. Moreover, in interpreting both the specification and the claims, all terms should be interpreted in the broadest possible manner consistent with the context. In particular, the terms “comprise” and “comprising” should be interpreted as referring to elements, components, or steps in a non-exclusive manner, indicating that the referenced elements, components, or steps may be present, or utilized, or combined with other elements, components, or steps that are not expressly referenced. Where the specification claims refer to at least one of something selected from the group consisting of A, B, C . . . and N, the text should be interpreted as requiring only one element from the group, not A plus N, or B plus N, etc.

What is claimed is:

1. An antenna measurement system for producing a 3D radiation pattern emanating from an antenna under test (AUT) at a test wavelength L, the AUT having a longest first linear dimension, and a longest second linear dimension orthogonal to the first linear dimension, the system comprising:
a first probe that traverses a first scanner over a distance D1 less than 2.4 times the longest first linear dimension; and
a second probe that traverses a second scanner over a distance D2 less than 2.4 times the longest second linear dimension;
wherein the AUT is rotatable with respect to at least one of the first and second scanners.

2. The antenna measurement system of claim 1, wherein the first scanner is distanced from the AUT by no more than 5λ.

3. The antenna measurement system of claim 1, wherein the first scanner is distanced from the AUT by no more than 4λ.

4. The antenna measurement system of claim 1, wherein each of the AUT and the first probe is rotatably carried by a carriage, and rotation of the AUT is orthogonal to a long axis of the first scanner.

5. The antenna measurement system of claim 1, wherein the AUT is rotatable with respect to each of the first and second scanners.

6. A method of producing a 3D radiation pattern for at least a first wavelength λ emanating from an antenna under test (AUT), the method comprising:
positioning the AUT between a first scanner having a first measuring probe and a second scanner having a second measuring probe; and
rotating at least one of the AUT and the first scanner with respect to one another;
capturing first data from the first probe and second data from the second probe, and using the first data to augment/extrapolate the second data.

7. The method of claim 6, further comprising using data from the first scanner to simulate a cylindrical scanning surface about the AUT, and using data from the second scanner to simulate a first planar scanning surface distanced from the AUT.

8. The method of claim 7, wherein the first simulated planar scanning surface is perpendicular to a long axis of the simulated cylindrical scanning surface.

9. The method of claim 7, wherein the first simulated planar scanning surface extends laterally beyond a radius of the simulated cylindrical scanning surface.

10. The method of claim 6, wherein the first simulated planar scanning surface is distanced from the simulated cylindrical scanning surface.

11. The method of claim 6, wherein the first simulated planar scanning surface is positioned within the simulated cylindrical scanning surface.

12. The method of claim 6, further comprising capturing third data from a third probe on a third scanner, and using the third data to simulate a second planar scanning surface, and to further augment/extrapolate the first data.

13. The method of claim 6, further comprising distancing the first scanner no more than 5λ. from the AUT.

14. The method of claim 6, further comprising distancing the first scanner no more than 4λ. from the AUT.
